(19) United States
(12) Patent Application Publication
(10) Pub. No.: US 2025/0244815 A1
(43) Pub. Date: Jul. 31, 2025

(54) Power Down Circuitry

(71) Applicant: ABB Schweiz AG, Baden (CH)

(72) Inventors: Thomas Keul, Freigericht (DE); Huan Shi, Hangzhou (CN); Haoran Li, Minden (DE); Yvan-Yongfei Qu, Hangzhou (CN); Wei Liu, Hangzhou (CN); Wendy Liu, Hangzhou (CN)

(73) Assignee: ABB Schweiz AG, Baden (CH)

(21) Appl. No.: 19/036,213

(22) Filed: Jan. 24, 2025

(30) Foreign Application Priority Data
Jan. 25, 2024 (EP) 24154049.1

(51) Int. Cl. G06F 1/30; G06F 1/3225; G06F 11/14

(52) U.S. Cl. CPC G06F 1/30; G06F 1/3225; G06F 11/1441

(57) ABSTRACT

A power down circuitry for a controller of a process control system includes at least one buffer capacitor for buffering sufficient energy to complete a power down sequence; a power voter configured to select the at least one buffer capacitor as energy source in response to detection of power failure; non-volatile memory for retaining process data following the detection of power failure; and logic circuitry configured to coordinate transfer of the process data to the non-volatile memory during the power down sequence.

### CROSS-REFERENCE TO RELATED APPLICATIONS

The instant application claims priority to European Patent Application No. 24154049.1, filed Jan. 25, 2024, which is incorporated herein in its entirety by reference.

### FIELD OF THE DISCLOSURE

The present disclosure generally relates to power down circuitry and methods for process control systems.

### BACKGROUND OF THE INVENTION

In the field of industrial process automation, controllers are typically provided with power down functionality which is operable to retain process values measured immediately prior to power failure for reuse upon power up. One example involves a conveyor belt which loads a ship with bulk material. Upon restart after power failure, the control application should continue with exactly the same value of load count as before the power failure. As process control systems increase in complexity, the challenge of implementing power down functionality in a cost effective manner becomes more challenging.

### BRIEF SUMMARY OF THE INVENTION

In one aspect, the present disclosure describes power down circuitry for a controller of a process control system, the power down circuitry comprising at least one buffer capacitor for buffering sufficient energy to complete a power down sequence; a power voter configured to select the at least one buffer capacitor as energy source in response to detection of power failure; non-volatile memory for retaining process data following the detection of power failure; and logic circuitry configured to coordinate transfer of the process data to the non-volatile memory during the power down sequence.

In this way, the power down circuitry may be implemented using cost-effective, small-size, and/or readily-available components. No batteries are necessary and process control execution tasks are not hindered by cyclic storage of data in non-volatile memory. The data storage time of the process data to be retained is practically unlimited. Large amounts of data can be retained at moderate hardware costs.

### BRIEF DESCRIPTION OF THE SEVERAL VIEWS OF THE DRAWING(S)

FIG. 1 is a diagram of a process control system for controlling an industrial process in accordance with the disclosure.

FIG. 2 is a block diagram representing a controller of the process control system of FIG. 1 which uses capacitor-buffered energy for power fail handling.

FIG. 3 is a block diagram of another example of the controller of FIG. 1.

FIG. 4 is a diagram of one example of a power down sequence in accordance with the disclosure.

FIG. 5 is a diagram of a further example of the power down sequence which is rationalized for expedited execution, in accordance with the disclosure.

### DETAILED DESCRIPTION OF THE INVENTION

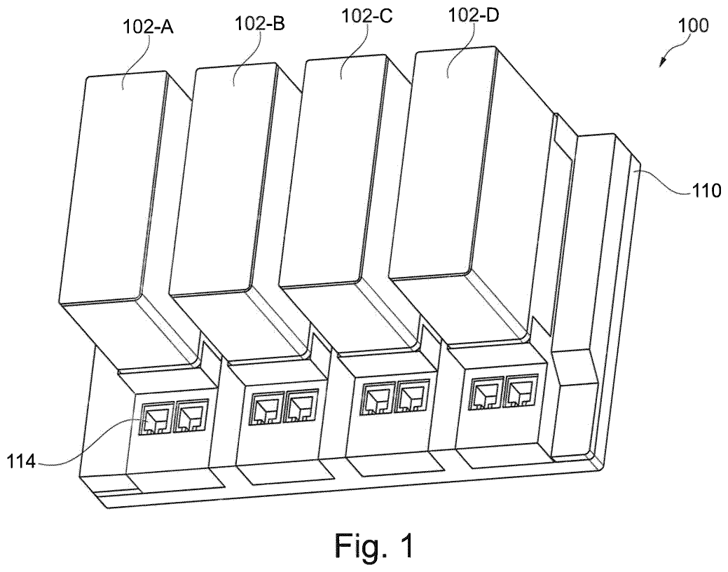

FIG. 1 illustrates a process control system 100 for controlling an industrial process carried out by an automation system (not shown). The process control system 100 comprises multiple controllers 102-A, 102-B, 102-C, 102-D, collectively referred to as controllers 102, which are physically and communicatively coupled to one another via a mounting termination unit (MTU) 110, commonly known as a backplane. The controllers 102 are configured to communicate with other components of the automation system, such as field devices, or an engineering tool as described herein. The engineering tool (typically implemented as a software package) is used to create configuration data for the process control system 100, which can be downloaded to the controllers 102. For the purposes of such communication, the controllers 102 are provided with Ethernet ports, such as that illustrated at 114, together with associated communications interface circuitry. Each of the controllers 102 furthermore comprises its own network switch.

Each of the controllers 102 is configured to control a respective process carried out by the automation system (not shown). The process control system 100 may find application in any field of industry where process automation is desired, such as energy, oil and gas, chemical, petrochemical, and so on. The controllers 102 handle process control and monitoring for the automation system by receiving input signals from sensors and instruments, and outputting control signals for controlling plant equipment such as pumps, valves, conveyors, mixers, and heaters. Any such sensor, instrument or plant equipment may form part of one or more of the field devices. The controllers 102 are configured to execute process control applications to generate the control signals on the basis of the input signals. Each control application may comprise control logic instructing the respective controller how to respond to all input signals with appropriate control signals to maintain normal functioning of the process. In one non-limiting example, the control application conforms to the international standard IEC 61131. Each of the controllers 102 comprises logic circuitry configured to execute the respective control application. The logic circuitry may comprise a CPU, MCU, SoC, FPGA, DSP, and/or an AI-engine, together with any memory to be used in the processing of signals. The logic circuitry may be further configured to perform any one or more of the other operations described herein.

One or more of the controllers 102 are furthermore provided with power down functionality which is operable to retain process values measured immediately prior to power failure for reuse upon power up. It is desirable to implement the power down circuitry in a cost-effective manner using small size components which are readily maintainable and which are not subject to constraints on their use or transportation.

According to the present disclosure, power down circuitry of the controller 102 is implemented using cost-efficient components, including at least one buffer capacitor (e.g., a standard capacitor) for buffering sufficient energy to complete a power down sequence, together with non-volatile memory (e.g., an eMMC card, or flash memory) for saving application data after detection of power failure by the power down circuitry. During normal operation, the at least one capacitor (e.g., a capacitor bank) is charged to a default voltage (e.g., 45V). In case of power failure, the energy stored in the at least one capacitor is used to move the process data to be retained from the DRAM of the controller 102 to the non-volatile storage. The power down circuitry may be further configured to perform a power up sequence to resume execution of the control application following restoration of power, whereby the process data retained in the non-volatile storage is moved back into the DRAM of the controller 102.

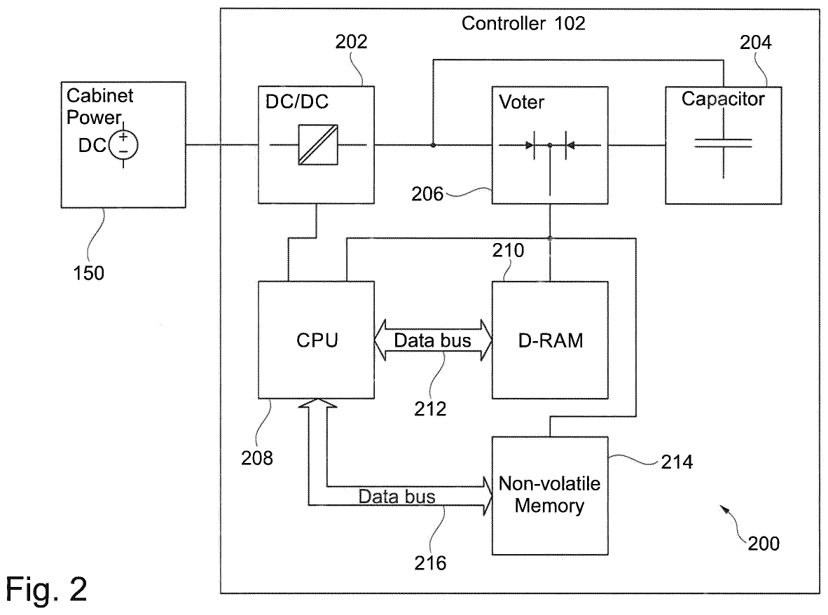

FIG. 2 is a block diagram illustrating the power down circuitry 200 of the controller 102. It will be understood that only those components of the controller 102 which are relevant for power fail handling are illustrated.

DC/DC converter 202 receives an input voltage (e.g., 24V) from an external power supply, referred to herein as a cabinet power supply 150, and converts the input voltage into a stabilized intermediate voltage (e.g., 5.1V), which is referred to as a primary or cabinet-side intermediate voltage. The DC/DC converter in one non-limiting example comprises a galvanic insulation, a current limiter, a fuse, and voltage monitoring circuitry.

Capacitor bank 204 stores energy for power fail handling. The stored energy in one limiting example is about 5 to 10 Joule. The charged capacitor bank 204 generates an intermediate voltage (e.g., 5.0V), which is referred to as a secondary or capacitor-side intermediate voltage.

Power voter 206 selects one of the two intermediate voltages for supply to circuitry of the controller 102, including at least its logic circuitry and memories, and optionally also certain peripherals. The power voter 206 is configured to select the highest voltage appearing at its inputs for provision to the controller circuitry. In the example illustrated in FIG. 2, the power voter 206 comprises two diodes connected in a reverse series configuration. The power voter 206 is thus operable to seamlessly bridge voltage dips in the cabinet-side intermediate voltage (e.g., 5.1V) by selecting the capacitor-side intermediate voltage (e.g., 5.0V). In a further example, the power voter 206 comprises power FETs with low pass-through resistance to keep losses caused by voltage drop low (e.g., in the mV range). By selecting a capacitor-side intermediate voltage which is lower than the cabinet-side intermediate voltage, the power down circuitry 200 functions in normal operation to supply the controller circuits with power delivered from the cabinet power supply 150 and not from the capacitor bank 204.

The logic circuitry 208 of the controller 102 comprises in this example a central processing unit (CPU) which communicates with dynamic random-access memory (DRAM) 210 via a data bus 212.

Non-volatile memory 214 provides storage capacity for the data to be retained upon power down. The non-volatile memory 214 in one example comprises an eMMC flash card. The CPU 208 communicates with the non-volatile memory via a data bus 216.

The power down sequence carried out by the power down circuitry 200 is as follows.

Beginning with normal operation in Step 1, the energy for controller 102 is delivered by the cabinet power supply 150. The capacitor bank 204 is fully charged with sufficient energy for the power down sequence to be completed. The CPU 208 executes the control application to generate and change process data during each control cycle. At least some of the process data are retain data which are to be used for the next control cycle or which are important for documenting the history of the control application. The retain data are stored in the DRAM but not necessarily in a linear address range, being spread over a wide address range of the DRAM.

Step 2 of the power down sequence comprises detection of power failure. The DC/DC converter 202 detects that the input voltage drops to a certain voltage level, for example a critical input voltage at which the DC/DC converter 202 can no longer generate the cabinet-side intermediate voltage reliably or safely, and generates a power fail detection signal. The DC/DC converter 202 may be provided for this purpose with a voltage monitor. The power fail detection signal may be low-pass filtered (e.g., about 20 ms) robustness against fluctuations in the input voltage. The power fail detection signal triggers the CPU 208 to begin power fail handling.

In Step 3, normal operation is finalized. The CPU 208 ensures that ongoing controller tasks are terminated fast and that no data inconsistencies occur.

In Step 4, peripherals such as Ethernet switches, physical layer components, superfluous CPU cores or FPGAs, oscillators, and interfaces are optionally turned off, to increase the amount of capacitor-stored energy which is available for the storage of the retain data. By “peripheral” is meant any component which is not involved in the transfer of retain data to non-volatile storage.

In Step 5, scattered retain data are optionally sorted. Retain data which are scattered in the DRAM 210 are sorted and stored in a linear address space of the DRAM 210, which also contains administration data for correct assignment of retain data to reestablish the application when power returns. For data integrity, a CRC checksum may be calculated for sections/blocks of compact (linear) stored retain data. For more efficient resource utilization, hardware-supported checksum calculations may be performed.

In Step 6, the retain data are transferred from DRAM 210 to the non-volatile memory 214. For example, the blocks of compact stored retain data are moved from the DRAM via the data bus 216, which may be a serial bus, to the non-volatile memory 214. Since data transfer rates between the CPU 208 and the non-volatile memory 214 are limited, regardless of which technology is used to implement them, the controller circuitry involved in the transfer must remain powered during this time.

In Step 7, subsequent to the transfer of the retain data, any remaining controller circuitry aside from the non-volatile storage 214 is turned off. To conserve energy, the CPU 208 may operate a switch to disconnect itself and the DRAM 210 from external power. In the case that the CPU 208 and DRAM 214 form part of a core or system on chip, it may be this component which is turned off. Simultaneously, the CPU 208 may reset its internal power supply (not shown) to prepare for the power up sequence to be carried out when external power returns. Additionally or alternatively, the CPU 208 may prepare an external reset circuit which provides the CPU/core with power when external power returns.

The power down sequence is thus completed with the retain values stored in non-volatile memory 214, optionally with data integrity ensured by one or more error detection and/or correction codes, such as CRC checksums. The non-volatile memory 214 remains powered by the capacitor bank 204. In one example, the non-volatile memory 214 remains powered for a predetermined amount of time (e.g., 0.5 s) after receiving the last data transfer. The power consumption of the non-volatile memory 214 in this period is lower than that of the CPU 208, such that energy is conserved by separating the power supply to the non-volatile memory 214 from that of the CPU 208.

In a variant, the retain data are not transferred directly to the non-volatile memory 214 itself, but are first stored in a cache belonging to the non-volatile memory 214 which has a faster access time than the non-volatile memory 214.

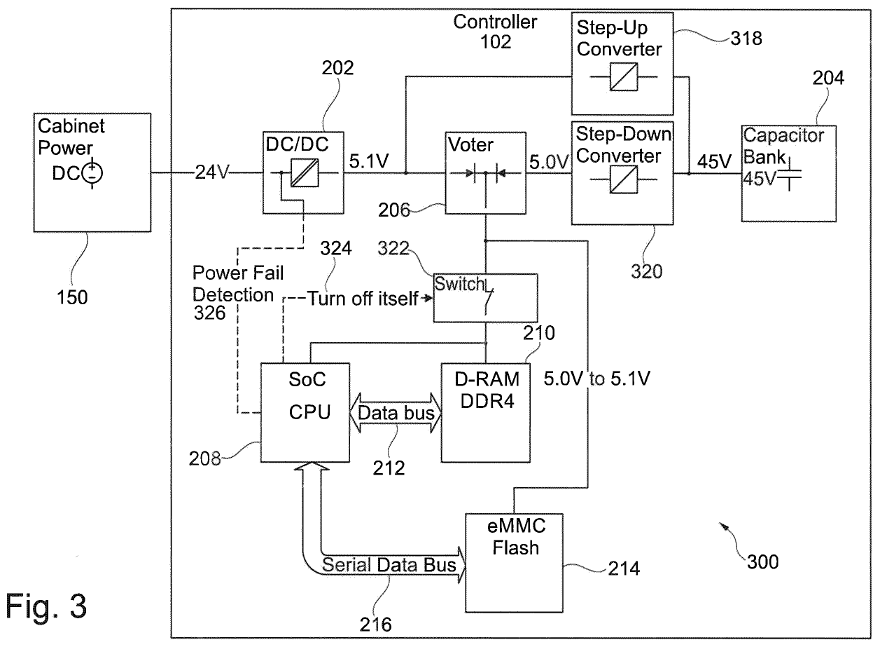

FIG. 3 illustrates the controller 102 comprising another example of power down circuitry 300 according to the present disclosure. The same reference numerals are used to indicate the same components as described with reference to FIG. 2. The power down circuitry 300 differs from the power down circuitry 200 in the following respects.

Step-up converter 318 increases the cabinet-side intermediate voltage to a higher level (e.g., 45V) and provides that voltage to the capacitor bank 204. Alternatively, the input to the step-up converter 318 can be tapped from the input voltage provided by the cabinet power supply 150 (e.g., 24V). The capacitor bank 204 is thus charged to a voltage which is higher than discharged voltages (for example 8 to 9 times higher), which facilitates utilization of a high ratio of the stored energy. Stated differently, the step up to the higher voltage reduces the necessary dimensions of capacitors for the same energy storage conditions.

Step-down converter 320 decreases the higher capacitor voltage to the capacitor-side intermediate voltage as described above (e.g., 5V).

Switch 322 is operable by the CPU 208 to turn off the CPU 208 and the DRAM 210 to conserve energy. The switch 322 receives a control signal 324 from the CPU 208. After power up, the control signal 324 is set per default to turn on the switch 322.

Power fail detection signal 326 is output by the DC/DC converter 202 for initiating the power down sequence. The signal 326 indicates that the energy to supply the controller 102 can no longer be delivered by the external power supply 150. In one example, a comparator is used to detect that the input voltage is lower than a predefined threshold voltage level.

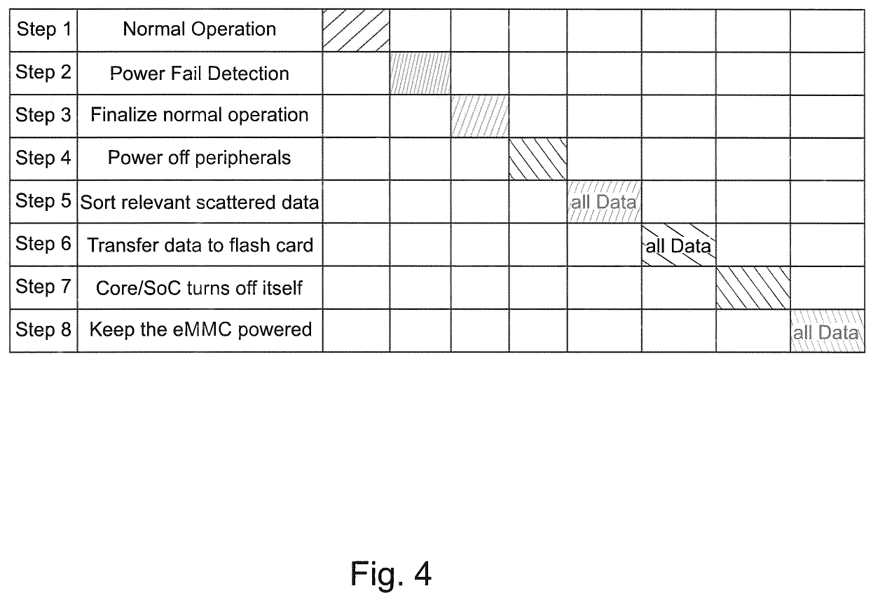

Example 1. FIG. 4 illustrates one example of the power down sequence, in which the steps are performed sequentially, with each step commencing upon completion of the preceding step.

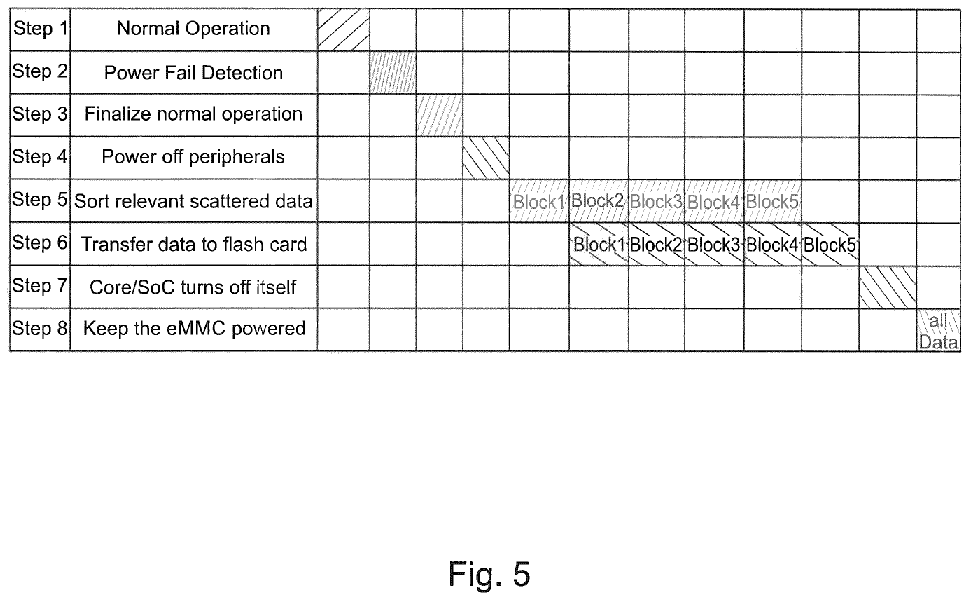

Example 2. FIG. 5 illustrates a further example of the power down sequence which is rationalized for expedited execution. The sequence of FIG. 5 differs from that FIG. 4 in that Steps 5 and 6 are executed in parallel rather than serially. Stated differently, whereas Step 6 of FIG. 4 does not commence until Step 6 completes, in FIG. 5, parts or blocks of retain data are sorted in Step 5 and then immediately transferred in Step 6 while other blocks are being sorted in Step 5, to save time and energy. Energy savings permit utilization of smaller capacitors.

In any of the examples described herein, a power up sequence may be carried out when external power returns for recovery of the retain data. The power up sequence in the example of FIG. 3 may be started after the step-up voltage on the capacitor bank 204 reaches a setpoint voltage, so that the controller 102 is prepared for a further power failure. Alternatively, the control application may not generate new retain data before the capacitor bank 204 is sufficiently charged. The age of recovered retain data may be checked to ascertain that the retain values remain usable.

The logic circuitry 208 as described herein may be implemented using hardware, software, and/or firmware configured to perform any of the operations described herein. Hardware may comprise one or more processor cores, field-programmable gate arrays (FPGAs), application-specific integrated circuits (ASICs), application-specific standard products (ASSPs), system-on-a-chip systems (SOCs), complex programmable logic devices (CPLDs), etc. Software may be embodied as a software package, code, instructions, instruction sets and/or data recorded on at least one transitory or non-transitory computer readable storage medium. Firmware may be embodied as code, instructions or instruction sets and/or data hard-coded in memory devices (e.g., non-volatile memory devices).

If implemented in software, the functions can be stored on or transmitted over as one or more instructions or code on a computer-readable medium. Computer-readable media include computer-readable storage media. Computer-readable storage media can be any available storage media that can be accessed by a computer. By way of example, and not limitation, such computer-readable storage media can comprise FLASH storage media, RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, include compact disc (CD), laser disc, optical disc, digital versatile disc (DVD), floppy disk, and Blu-ray disc (BD), where disks usually reproduce data magnetically and discs usually reproduce data optically with lasers. Further, a propagated signal may be included within the scope of computer-readable storage media. Computer-readable media also includes communications media including any medium that facilitates transfer of a computer program from one place to another. A connection, for instance, can be a communications medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio and microwave are included in the definition of communications medium. Combinations of the above should also be included within the scope of computer-readable media.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

It has to be noted that embodiments of the invention are described with reference to different categories. In particular, some examples are described with reference to methods whereas others are described with reference to apparatus. However, a person skilled in the art will gather from the description that, unless otherwise notified, in addition to any combination of features belonging to one category, also any combination between features relating to different category is considered to be disclosed by this application. However, all features can be combined to provide synergetic effects that are more than the simple summation of the features.

While the invention has been illustrated and described in detail in the drawings and foregoing description, such illustration and description are to be considered exemplary and not restrictive. The invention is not limited to the disclosed embodiments. Other variations to the disclosed embodiments can be understood and effected by those skilled in the art, from a study of the drawings, the disclosure, and the appended claims.

The mere fact that certain measures are recited in mutually different dependent claims does not indicate that a combination of these measures cannot be used advantageously.

Any reference signs in the claims should not be construed as limiting the scope.

In the present disclosure, the power voter may comprise a plurality of inputs each configured to receive power from a respective power source, wherein at least one of the power sources comprises the at least one capacitor bank. Another of the power sources may comprise an external power source, for example a cabinet power source. The power voter may comprise a plurality of diodes connected in a reverse series configuration with a common output. The power voter may be configured to select the highest voltage appearing at its inputs for provision at its output to the controller circuitry. In this way, the power voter is operable to provide bump-less bridging between power sources.

The power down circuitry may comprise a DC/DC converter configured to convert an input voltage provided by an external power source into a primary intermediate voltage for supplying power to the controller during normal operation. The at least one buffer capacitor meanwhile provides a secondary intermediate voltage for supplying power to the controller in the event of failure of an external power source. The level of the secondary intermediate voltage may be selected to be lower than the primary intermediate voltage such that the primary intermediate voltage is selected by the power voter during normal operation. In the event of power failure, reduction of the primary intermediate voltage causes the power voter to select the secondary intermediate voltage.

The power down circuitry may comprise power fail detection circuitry configured to generate a power fail detection signal upon power down. The power fail detection signal may be used by the logic circuitry for initiating the power down sequence. In one example, the logic circuitry is configured to initiate the power down sequence directly in response to receiving the power fail detection signal. In another example, the logic circuitry is configured to delay initiation of the power down sequence directly following receipt of the power fail detection signal. By delaying the power down sequence, normal operation may continue for a certain amount of time using energy sourced from the at least one buffer capacitor so as to bridge voltage dips from the external power source for more reliable operation of the process control system. The power fail detection circuitry may comprise a comparator configured to detect that the input voltage provided by the external power source is lower than a predefined threshold voltage level and correspondingly to generate the power fail detection signal. The power fail detection circuitry and/or the comparator form part of the DC/DC converter, in one example.

The power down circuitry may comprise a step-up converter configured to increase the input voltage provided by the external power source and/or the primary intermediate voltage provided by the DC/DC converter to a higher voltage and to provide the higher voltage to the at least one capacitor. The power down circuitry may comprise a step-down converter configured to decrease the higher voltage to the secondary intermediate voltage level for input to the power voter. Step up to the higher voltage in this way may reduce the necessary dimensions of the at least one capacitor.

The power down circuitry may comprise a switch which is operable by the logic circuitry to cut power to one or more components to conserve energy during the power down sequence. The components to which power is to be cut may include the logic circuitry itself once its roll in coordinating the power down sequence has been fulfilled. The switch may receive a control signal from the logic circuitry. The control signal may be set per default to turn on the switch.

The logic circuitry may be configured to coordinate the transfer of the process data to the non-volatile memory in a block wise manner. The logic circuitry may be configured to sort the process data for transfer to the non-volatile memory. The logic circuitry may be configured to sort and transfer the process data in parallel. The logic circuitry may be configured to transfer a first block of process data to the non-volatile memory while sorting a second, different block of process data in parallel, to mitigate time and energy costs of the data transfer.

According to a second aspect, there is provided a controller for a process control system, the controller comprising the power down circuitry of the first aspect. The controller may be configured to execute a control application for controlling an industrial process. In one example, logic circuitry of the power down circuitry may be implemented by the same logic circuitry which executes the control application. The control application may generate process data which may be obtained or extracted by the controller for retention upon power failure. The controller may be configured to store process data in non-volatile storage for a predetermined amount of time, for example at minimum for one hour after power failure. The controller may frequently update the process data to be retained during normal operation until power failure. For example, the controller may periodically place the process data to be retained in static/dynamic RAM, which has an infinitive number of writing cycles and a fast access time, before writing the process data into non-volatile storage (such as F-RAM, M-RAM or nvSRAM) upon power down.

According to a third aspect, there is provided a process control system comprising the power down circuitry of the first aspect and/or the controller of the second aspect.

According to a fourth aspect, there is provided an industrial automation system comprising the power down circuitry of the first aspect and/or the controller of the second aspect and/or the process control system of the third aspect.

According to a fifth aspect, there is provided a power down method. The method comprises: buffering sufficient energy to complete a power down sequence using at least one buffer capacitor; selecting the at least one buffer capacitor as energy source in response to detection of power failure; coordinating the transfer of process data to non-volatile memory during the power down sequence; and retaining the process data in non-volatile memory following the detection of power failure.

The method of the fifth aspect may be (at least partially) computer implemented. Optional features of the first aspect may form part of any of the second-fifth aspects, mutatis mutandis.

According to a sixth aspect, there is provided a computing system configured to perform the method of the fifth aspect.

According to a seventh aspect, there is provided a computer program (product) comprising instructions which, when executed by a computing system, enable or cause the computing system to perform the method of the fifth aspect.

According to an eighth aspect, there is provided a computer-readable (storage) medium comprising instructions which, when executed by a computing system, enable or cause the computing system to perform the method of the fifth aspect. The computer-readable medium may be transitory or non-transitory, volatile or non-volatile.

By “sufficient” is meant that the energy stored in the at least one buffer capacitor is at least the amount of energy needed for the power down sequence and preferably more than necessary for the power down sequence.

By “(process) automation system” is meant an industrial plant or production plant comprising one or more pipelines, production lines, and/or assembly lines for transforming one or more educts into a product and/or for assembling one or more components into a final product.

By “process data” is meant any data used by the automation system in relation to the production process. In particular, the process data may comprise process values which are used in one or more control loops. Typically, such process values are stored in volatile memory during normal operation. The process data may additionally or alternatively comprise other data which are generated and/or used during operation, for example I/O signals, log data, configuration data, administration data, and/or error counters.

The term “obtaining”, as used herein, may comprise, for example, receiving from another system, device, or process; receiving via an interaction with a user; loading or retrieving from storage or memory; measuring or capturing using sensors or other data acquisition devices.

The term “determining”, as used herein, encompasses a wide variety of actions, and may comprise, for example, calculating, computing, processing, deriving, investigating, looking up (e.g., looking up in a table, a database or another data structure), ascertaining, and the like. Also, “determining” may comprise receiving (e.g., receiving information), accessing (e.g., accessing data in a memory), and the like. Also, “determining” may comprise resolving, selecting, choosing, establishing and the like.

The term “comprising” does not exclude other elements or steps. Furthermore, the terms “comprising”, “including”, “having” and the like may be used interchangeably herein.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A power down circuitry for a controller of a process control system, the power down circuitry comprising:
at least one buffer capacitor for buffering sufficient energy to complete a power down sequence;
a power voter configured to select the at least one buffer capacitor as energy source in response to detection of power failure;
non-volatile memory for retaining process data following the detection of power failure; and
logic circuitry configured to coordinate transfer of the process data to the non-volatile memory during the power down sequence.

2. The power down circuitry according to claim 1, wherein the power voter comprises a plurality of inputs each configured to receive power from a respective power source, wherein at least one of the power sources comprises at least one capacitor bank.

3. The power down circuitry according to claim 2, wherein another of the power sources comprises an external power source.

4. The power down circuitry according to claim 2, wherein the power voter is configured to select the highest voltage appearing at its inputs for provision at its output to power the controller.

5. The power down circuitry according to claim 1, wherein the power voter comprises a plurality of diodes connected in a reverse series configuration with a common output.

6. The power down circuitry according to claim 1, further comprising a DC/DC converter configured to convert an input voltage provided by an external power source into a primary intermediate voltage for supplying power to the controller during normal operation, wherein the at least one buffer capacitor provides a secondary intermediate voltage for supplying power to the controller in the event of failure of an external power source.

7. The power down circuitry according to claim 6, wherein the secondary intermediate voltage is selected to be lower than the primary intermediate voltage such that the primary intermediate voltage is selected by the power voter during normal operation, and wherein, in the event of power failure, reduction of the primary intermediate voltage causes the power voter to select the secondary intermediate voltage.

8. The power down circuitry according to claim 1, further comprising power fail detection circuitry configured to generate a power fail detection signal upon power down, wherein the power fail detection signal is used by the logic circuitry for initiating the power down sequence.

9. The power down circuitry according to claim 1, further comprising a step-up converter configured to increase an input voltage provided by an external power source and/or a primary intermediate voltage provided by a DC/DC converter to a higher voltage and to provide the higher voltage to the at least one capacitor.

10. The power down circuitry according to claim 9, further comprising a step-down converter configured to decrease the higher voltage to a secondary intermediate voltage level for input to the power voter.

11. The power down circuitry according to claim 1, further comprising a switch which is operable by the logic circuitry to cut power to one or more components to conserve energy during the power down sequence.

12. A power down method comprising:
buffering sufficient energy to complete a power down sequence using at least one buffer capacitor;
selecting the at least one buffer capacitor as energy source in response to detection of power failure;
coordinating the transfer of process data to non-volatile memory during the power down sequence; and
retaining the process data in non-volatile memory following the detection of power failure.
